(19) United States
(12) Patent Application Publication
(10) Pub. No.: US 2008/0139002 A1
(43) Pub. Date: Jun. 12, 2008

(54) Liquid chemical supply apparatus for supplying liquid chemical onto substrate, and semiconductor device fabrication method using liquid chemical supply apparatus

(76) Inventor: Hirokazu Kato, Zushi-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/000,271

(22) Filed: Dec. 11, 2007

(30) Foreign Application Priority Data
Dec. 11, 2006 (JP) 2006-333389

(51) Int. Cl. H01L 21/31; B05C 11/10

(52) U.S. Cl. 438/782; 118/600; 257/E21.24

(57) ABSTRACT

A liquid chemical supply apparatus includes a storage unit, addition unit, and nozzle unit. The storage unit stores a liquid chemical. The addition unit adds, to the liquid chemical supplied from the storage unit, a modifier in an amount corresponding to the degree of deterioration of the liquid chemical. The nozzle unit supplies, onto a substrate, the liquid chemical to which the modifier is added.

### CROSS-REFERENCE TO RELATED APPLICATIONS

This application is based upon and claims the benefit of priority from prior Japanese Patent Application No. 2006-333389, filed Dec. 11, 2006, the entire contents of which are incorporated herein by reference.

### BACKGROUND OF THE INVENTION

1. Field of the Invention

The present invention relates to a liquid chemical supply apparatus for supplying a liquid chemical for Spin On Glass (SOG) or the like onto a substrate, and a semiconductor device fabrication method using the liquid chemical supply apparatus.

2. Description of the Related Art

The fabrication of semiconductor devices uses an SOG material as an intermediate film in a multilayered resist process or as an interlayer dielectric film. However, the SOG material generally has low storage stability because its gelation irreversibly progresses. Therefore, a bottle containing a liquid chemical (to be referred to as an SOG liquid chemical hereinafter) containing an SOG material whose term of guarantee has expired is discarded. This increases the amount of wasted SOG liquid chemical.

Various techniques have been disclosed as countermeasures. As an example, Jpn. Pat. Appln. KOKAI Publication No. 2003-100729 has disclosed a technique using a semiconductor fabrication apparatus for performing SOG coating, characterized by comprising a portion that stores the solid component of an SOG liquid chemical, a portion that stores a solvent, and a portion that mixes the solid component and solvent at a certain ratio. This technique has the merit that the amount of wasted liquid chemical reduces because the liquid chemical is prepared inside the apparatus in accordance with the use amount.

Unfortunately, this method increases the size of the semiconductor fabrication apparatus for performing SOG coating because the liquid chemical manufacturing facility is incorporated into the apparatus. In addition, it is difficult to manufacture some SOG materials by mixing the solid component and solvent.

### BRIEF SUMMARY OF THE INVENTION

According to a first aspect of the present invention, there is provided A liquid chemical supply apparatus comprising: a storage unit which stores a liquid chemical; an addition unit which adds, to the liquid chemical supplied from the storage unit, a modifier in an amount corresponding to a degree of deterioration of the liquid chemical; and a nozzle unit which supplies, onto a substrate, the liquid chemical to which the modifier is added.

According to a second aspect of the present invention, there is provided A liquid chemical supply apparatus comprising: a storage unit which stores a liquid chemical, and in which the liquid chemical does not deteriorate regardless of a time having elapsed since the storage of the liquid chemical is started; an addition unit which receives the liquid chemical supplied from the storage unit, and in which the liquid chemical deteriorates with a time having elapsed since the liquid chemical is supplied from the storage unit, the addition unit adding, to the liquid chemical, a modifier in an amount corresponding to a degree of deterioration of the liquid chemical; and a nozzle unit which supplies, onto a substrate, the liquid chemical to which the modifier is added.

According to a third aspect of the present invention, there is provided a semiconductor device fabrication method comprising: adding, to a liquid chemical supplied from a storage unit storing the liquid chemical, a modifier in an amount corresponding to a degree of deterioration of the liquid chemical; supplying, onto a substrate, the liquid chemical to which the modifier is added; and forming a film by using the liquid chemical supplied onto the substrate.

### BRIEF DESCRIPTION OF THE SEVERAL VIEWS OF THE DRAWING

FIG. 1 is a view showing the arrangement of a liquid chemical supply apparatus according to a first embodiment of the present invention;

FIG. 2 is a graph showing the relationship between the degree of deterioration of an SOG liquid chemical and the water content in the SOG liquid chemical required to form a rectangular shape in the first embodiment;

FIG. 3 is a view showing the arrangement of a liquid chemical supply apparatus according to a second embodiment of the present invention;

FIG. 4 is a graph showing the relationship between the degree of deterioration of an SOG liquid chemical and the water content in the SOG liquid chemical required to form a rectangular shape in the second embodiment;

FIG. 5 is a view showing the arrangement of a liquid chemical supply apparatus according to a third embodiment of the present invention; and

FIG. 6 is a graph showing the relationship between the degree of deterioration of an SOG liquid chemical and the water content in the SOG liquid chemical required to allow an intermediate dielectric film to have a predetermined dielectric constant in the third embodiment.

### DETAILED DESCRIPTION OF THE INVENTION

Embodiments of the present invention will be explained below with reference to the accompanying drawing. In the following explanation, the same reference numerals denote the same parts throughout the drawing.

### First Embodiment

First, a liquid chemical supply apparatus of the first embodiment of the present invention will be explained below. This liquid chemical supply apparatus supplies a liquid chemical onto a semiconductor substrate, and includes, midway along the supply path, a mechanism for adding water (e.g., pure water) or the like to the liquid chemical as a modifier of the liquid chemical. This embodiment discloses an example in which an SOG liquid chemical is used as an interlayer in a three-layered resist process. That is, an organic film is formed on a semiconductor substrate, and the liquid chemical supply apparatus of this embodiment coats the organic film with the SOG liquid chemical. In addition, an SOG film formed by the SOG liquid chemical is coated with a resist film, and a resist pattern is formed in a photolithography step.

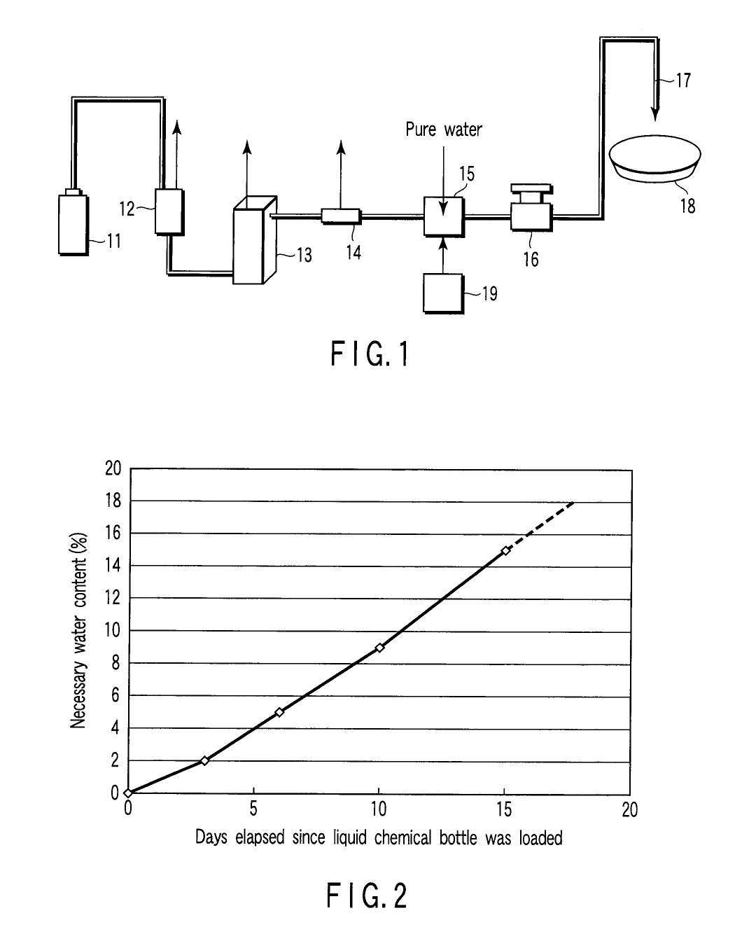

FIG. 1 is a view showing the arrangement of the liquid chemical supply apparatus of the first embodiment. As shown in FIG. 1, this liquid chemical supply apparatus includes a bottle 11, tank unit 12, pump unit 13, filter unit 14, addition adjusting unit (e.g., buffer tank) 15, valve 16, nozzle 17, and addition amount controller 19. The bottle 11 and tank unit 12 form a storage unit for storing the liquid chemical. The addition adjusting unit 15 and addition amount controller 19 form an addition unit for adding a modifier to the liquid chemical.

The bottle 11 is loaded in the liquid chemical supply apparatus, and contains the SOG liquid chemical. The SOG liquid chemical in the bottle 11 is supplied to a delivery pipe, and temporarily stored in the tank unit 12 through the delivery pipe. The SOG liquid chemical in the tank unit 12 is supplied to the pump unit 13. The SOG liquid chemical supplied to the pump unit 13 is pumped up by the pump unit 13, and supplied to the addition adjusting unit 15 through the filter unit 14. The filter unit 14 removes dust mixed in the SOG liquid chemical. The addition amount controller 19 is connected to the addition adjusting unit 15. The addition amount controller 19 controls the amount of modifier, e.g., the amount of water to be added to the SOG liquid chemical, in accordance with the time having elapsed since the bottle containing the SOG liquid chemical is loaded in the apparatus. Under the control of the addition amount controller 19, the addition adjusting unit 15 adds, to the SOG liquid chemical, the modifier, e.g., water in the amount set in accordance with the time having elapsed since the bottle 11 containing the SOG liquid chemical is loaded in the apparatus. The SOG liquid chemical to which water is added by the addition adjusting unit 15 is discharged onto a semiconductor substrate (wafer) 18 from the nozzle 17 through the valve 16.

The operation of supplying the SOG liquid chemical onto the semiconductor substrate by using the liquid chemical supply apparatus having the above arrangement will be explained in detail below.

First, it is necessary to obtain an appropriate water addition amount corresponding to the degree of deterioration (or degree of modification) of the SOG liquid chemical. When the SOG liquid chemical deteriorates, its molecular weight rises, and the sectional shape of the resist pattern formed on this SOG film forms an overhang. On the other hand, when the water content in the SOG liquid chemical increases, the sectional shape of the resist pattern changes from a rectangular shape to a trapezoidal shape. The sectional shape of the resist pattern is desirably a rectangular shape. In this embodiment, therefore, the water content in the SOG liquid chemical by which the sectional shape of the resist pattern was a rectangle was obtained.

FIG. 2 shows the relationship between the degree of deterioration of the SOG liquid chemical and the water content in the SOG liquid chemical necessary to obtain a rectangular shape. The abscissa indicates days having elapsed since the bottle 11 containing the SOG liquid chemical is loaded in the liquid chemical supply apparatus, thereby representing the degree of deterioration of the SOG liquid chemical. The ordinate indicates the water content in the SOG liquid chemical necessary to make the sectional shape of the resist pattern rectangular.

The relationship shown in FIG. 2 reveals that it is necessary to increase the water content in the SOG liquid chemical as the number of days increases since the SOG liquid chemical bottle is loaded. More specifically, the following processing was performed. For example, three days had elapsed at a certain time since the bottle 11 containing the SOG liquid chemical was loaded in the apparatus, i.e., the SOG liquid chemical was injected into the apparatus. Therefore, the addition amount controller 19 injected water into the addition adjusting unit 15 as a buffer tank to set the water content in the SOG liquid chemical at 2%. Also, six days had elapsed at another time since the bottle 11 containing the SOG liquid chemical was loaded in the apparatus. Hence, water was injected into the addition adjusting unit 15 to set the water content in the SOG liquid chemical at 5%. Furthermore, 15 days had elapsed at still another time since the bottle 11 containing the SOG liquid chemical was loaded in the apparatus. Accordingly, water was injected into the addition adjusting unit 15 to set the water content in the SOG liquid chemical at 15%.

Resist patterns were formed on SOG films formed by the SOG liquid chemicals given the predetermined water contents described above when the respective corresponding numbers of days had elapsed, and these resist patterns were observed. Consequently, the sectional shape of each resist pattern remained a perfect rectangular shape. The sensitivity of each resist pattern also remained almost constant. In addition, no pattern collapse was found when a defect test was conducted on these resist patterns.

On the other hand, it is known that when more than 15 days have elapsed since the bottle 11 containing the SOG liquid chemical is loaded in the apparatus, the coating properties become abnormal and the thickness of a film to be formed falls outside the range of specifications even if water is added. Therefore, the bottle 11 containing the SOG liquid chemical and loaded in the apparatus was discarded, and the SOG liquid chemical injected into the apparatus was purged.

Note that when the conventional technique that did not add any water to the SOG liquid chemical was used, if more than six days had elapsed since the bottle 11 containing the SOG liquid chemical was loaded in the apparatus, the sectional shape of a resist pattern formed on the SOG film formed an overhang, and pattern collapse frequently occurred. Accordingly, it was necessary to discard the SOG liquid chemical when more than six days had elapsed since the SOG liquid chemical bottle was loaded in the apparatus, so the SOG liquid chemical was wasted. Also, even when six days had not elapsed yet since the SOG liquid chemical bottle was loaded in the apparatus, the sectional shape of the resist pattern slightly changed due to the time that had elapsed since the SOG liquid chemical bottle was loaded, indicating low dimensional controllability.

By contrast, the first embodiment makes it possible to maintain the rectangular sectional shape of a resist pattern formed on the SOG film regardless of the time having elapsed since the bottle 11 containing the SOG liquid chemical is loaded in the apparatus. That is, the use period of even a liquid chemical whose performance readily deteriorates can be prolonged while a predetermined performance is maintained.

The degree of deterioration of the liquid chemical may also be determined on the basis of at least one of the time having elapsed since the liquid chemical is supplied to the internal storage unit of the liquid chemical supply apparatus, the molecular weight of the liquid chemical, and the film thickness of a film formed by the liquid chemical. The molecular weight of the liquid chemical is the molecular weight of the solute of the liquid chemical. The time having elapsed since the liquid chemical is supplied to the storage unit is one of the time having elapsed since the bottle containing the SOG liquid chemical is loaded in the liquid chemical supply apparatus, the time having elapsed since the liquid chemical is externally supplied to the apparatus, and the time having elapsed since the storage unit in the apparatus starts storing the liquid chemical. Assume that, in this case, the liquid chemical does not deteriorate outside the apparatus and starts deteriorating when the bottle is loaded in the apparatus, when the liquid chemical is supplied to the apparatus, or when the storage of the liquid chemical is started in the apparatus.

Note that the first embodiment has disclosed an example in which the liquid chemical supply apparatus is used to supply the liquid chemical onto a semiconductor substrate and form a coating film on it. However, the first embodiment is not limited to this example. Note also that water is used as the modifier of the SOG liquid chemical in the first embodiment, but an alcohol-based material may also be used.

When water or an alcohol-based material having high affinity for the solid component of the SOG material is added to the SOG liquid chemical, the volatilizing rate of the solvent decreases at the time of coating of the SOG liquid chemical, so the denseness of the SOG film increases. Even when a film is formed by coating of the SOG liquid chemical having a high molecular weight, a dense film equivalent to that obtained before the molecular weight rises can be obtained by adding water or an alcohol-based material to the SOG liquid chemical. This makes it possible to obtain an SOG film having physical properties equivalent to those obtained before the molecular weight rises, and practically largely extends the life of the liquid chemical.

In addition, the SOG liquid chemical has the characteristic that its molecular weight rises with time, so the molecular weight can also be used as the index of the degree of deterioration of the liquid chemical. Also, the viscosity rises when the molecular weight rises, and this increases the film thickness of an SOG film formed by the SOG liquid chemical. Therefore, the film thickness of the SOG film can also be used as the index of the degree of deterioration. That is, the degree of deterioration of the liquid chemical may also be determined by at least one of the molecule weight of the liquid chemical and the film thickness of a film formed by the liquid chemical.

Furthermore, the amount of modifier to be added to the SOG liquid chemical may also be determined, regardless of the degree of deterioration of the SOG liquid chemical, such that at least one of the sensitivity of a resist film formed on the SOG film, the shape of a resist pattern, and the collapse resistance of the resist pattern remains the same. For example, the resist sensitivity rises when an SOG film is formed by using an SOG liquid chemical having a high molecular weight and a resist pattern is formed on this SOG film. However, when water or an alcohol-based material is added to the SOG liquid chemical having a high molecular weight, the resist sensitivity of a resist pattern formed on the SOG film lowers and becomes close to that of a resist pattern formed on an SOG film formed by using an SOG liquid chemical having a low molecular weight. Also, when an SOG film is formed by using an SOG liquid chemical having a high molecular weight and a resist pattern is formed on this SOG film, the sectional shape of the resist pattern generally forms an overhang. However, when water or an alcohol-based material is added to the SOG liquid chemical having a high molecular weight, a resist pattern formed on the SOG film has a favorable sectional shape similar to that of a resist pattern formed on an SOG film formed by using an SOG liquid chemical having a low molecular weight. In addition, when an SOG film is formed by using an SOG liquid chemical having a high molecular weight and a resist pattern is formed on this SOG film, the resist pattern easily collapses. However, when water or an alcohol-based material is added to the SOG liquid chemical having a high molecular weight, the collapse resistance of a resist pattern formed on the SOG film rises and becomes close to that of a resist pattern formed on an SOG film formed by using an SOG liquid chemical having a low molecular weight.

Examples of a semiconductor device fabricated by using the liquid chemical supply apparatus of the first embodiment are an FPD (Flat Panel Display) for use in liquid crystal display and MEMS

### (Micro-Electro-Mechanical Systems).

### Second Embodiment

A liquid chemical supply apparatus of the second embodiment of the present invention will be explained below. The same reference numerals as in the arrangement of the first embodiment denote the same parts. As in the first embodiment, this liquid chemical supply apparatus supplies a liquid chemical onto a semiconductor substrate, and includes, midway along the supply path, a mechanism that adds a modifier such as water (e.g., pure water) to the liquid chemical. The second embodiment also discloses an example in which an SOG liquid chemical is used as an interlayer in a three-layered resist process. In the second embodiment, a bottle containing the SOG liquid chemical is loaded in a refrigerated state in an apparatus. Therefore, the SOG liquid chemical does not deteriorate with time even after the bottle is loaded in the apparatus. In other words, the SOG liquid chemical does not deteriorate regardless of the time having elapsed since an internal storage unit of the apparatus starts storing the SOG liquid chemical. The SOG liquid chemical starts deteriorating when it is supplied from the bottle.

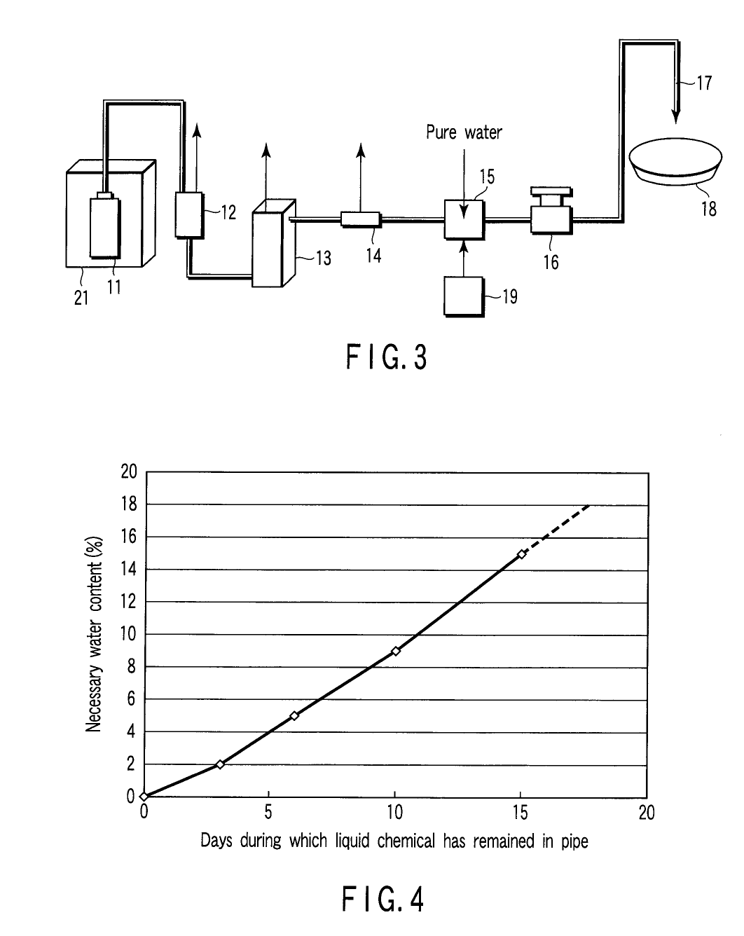

FIG. 3 is a view showing the arrangement of the liquid chemical supply apparatus of the second embodiment. As shown in FIG. 3, this liquid chemical supply apparatus includes a refrigerating storage unit 21, bottle 11, tank unit 12, pump unit 13, filter unit 14, addition adjusting unit 15, valve 16, nozzle 17, and addition amount controller 19. The bottle 11 containing the SOG liquid chemical is loaded in the refrigerating storage unit 21. The SOG liquid chemical in the bottle 11 loaded in the refrigerating storage unit 21 is refrigerated, and supplied to a delivery pipe as needed. The SOG liquid chemical supplied to the delivery pipe is temporarily stored in the tank unit 12 through the delivery pipe. After that, the SOG liquid chemical is supplied to the addition adjusting unit 15 through the filter unit 14.

Since the bottle 11 is loaded in the refrigerating storage unit 21, the SOG liquid chemical in the bottle 11 is refrigerated. Therefore, the SOG liquid chemical does not deteriorate with time even after the bottle 11 is loaded in the apparatus, and starts deteriorating when supplied from the bottle 11 (or the refrigerating storage unit 21) to the delivery pipe. Accordingly, the degree of deterioration (or degree of modification) of the SOG liquid chemical can be estimated from the time during which the SOG liquid chemical supplied from the bottle 11 (or the refrigerating storage unit 21) stays in the delivery pipe. When the SOG liquid chemical deteriorates, its molecular weight rises, and the shape of a resist pattern formed on this SOG film forms an overhang. On the other hand, when the water content in the SOG liquid chemical increases, the sectional shape of the resist pattern changes from a rectangular shape to a trapezoidal shape. In this embodiment, therefore, the water content in the SOG liquid chemical by which the sectional shape of the resist pattern was a rectangle was obtained.

FIG. 4 shows the relationship between the degree of deterioration of the SOG liquid chemical and the water content in the SOG liquid chemical necessary to obtain a rectangular shape. The abscissa indicates days having elapsed since the SOG liquid chemical is supplied from the bottle 11, i.e., days during which the SOG liquid chemical stays in the delivery pipe, thereby representing the degree of deterioration of the SOG liquid chemical. The ordinate indicates the water content in the SOG liquid chemical necessary to make the sectional shape of the resist pattern rectangular.

The relationship shown in FIG. 4 reveals that it is necessary to increase the amount of water to be added to the SOG liquid chemical as the number of days during which the SOG liquid chemical stays in the delivery pipe increases. More specifically, the following processing was performed. For example, three days had elapsed at a certain time since the SOG liquid chemical was supplied to the addition adjusting unit (buffer tank) 15 from the bottle 11 in the refrigerating storage unit 21. Therefore, the addition amount controller 19 injected water into the addition adjusting unit 15 to set the water content in the SOG liquid chemical at 2%. Also, six days had elapsed at another time since the SOG liquid chemical was supplied to the addition adjusting unit 15 from the bottle 11 in the refrigerating storage unit 21. Hence, water was injected into the addition adjusting unit 15 to set the water content in the SOG liquid chemical at 5%. Furthermore, 15 days had elapsed at still another time since the SOG liquid chemical was supplied to the addition adjusting unit 15 from the bottle 11 in the refrigerating storage unit 21. Accordingly, water was injected into the addition adjusting unit 15 to set the water content in the SOG liquid chemical at 15%.

Resist patterns were formed on SOG films formed by the SOG liquid chemicals given the predetermined water contents described above when the respective corresponding numbers of days had elapsed, and these resist patterns were observed. Consequently, the sectional shape of each resist pattern remained a perfect rectangular shape. The sensitivity of each resist pattern also remained almost constant. In addition, no pattern collapse was found when a defect test was conducted on these resist patterns.

On the other hand, it is known that when more than 15 days have elapsed since the SOG liquid chemical is supplied to the addition adjusting unit (buffer tank) 15 from the bottle 11 in the refrigerating storage unit 21, the coating properties become abnormal and the thickness of a film to be formed falls outside the range of specifications even if water is added. Therefore, the SOG liquid chemical staying in the pipe of the apparatus was purged.

In the second embodiment as explained above, the bottle 11 containing the SOG liquid chemical is loaded in the refrigerating storage unit 21, so the SOG liquid chemical does not deteriorate with time even after the bottle 11 is loaded in the apparatus. The SOG liquid chemical starts deteriorating when supplied from the bottle 11 (or the refrigerating storage unit 21). Accordingly, the modifier is added to the SOG liquid chemical in an amount set in accordance with the time having elapsed since the SOG liquid chemical is supplied from the bottle 11 (or the refrigerating storage unit 21). This makes it possible to form a desired resist pattern, i.e., a resist pattern having a rectangular sectional shape on an SOG film formed by the SOG liquid chemical.

The degree of deterioration of the liquid chemical may also be determined on the basis of at least one of the time having elapsed since the liquid chemical is supplied from the storage unit, the molecular weight of the liquid chemical, and the film thickness of a film formed by the liquid chemical. The time having elapsed since the liquid chemical is supplied from the storage unit is the time having elapsed since the SOG liquid chemical is supplied to the delivery pipe from the bottle (or the refrigerating storage unit), i.e., the time during which the SOG liquid chemical supplied from the bottle (or the refrigerating storage unit) stays in the delivery pipe.

The second embodiment makes it possible to maintain the rectangular sectional shape of a resist pattern formed on the SOG film regardless of the time having elapsed since the bottle 11 containing the SOG liquid chemical is loaded in the apparatus. That is, the use period of even a liquid chemical whose performance readily deteriorates can be prolonged while a predetermined performance is maintained. Note that water is used as the modifier of the SOG liquid chemical in the second embodiment, but an alcohol-based material may also be used. The rest of the arrangement and effects are the same as in the first embodiment described earlier.

### Third Embodiment

A liquid chemical supply apparatus of the third embodiment of the present invention will be explained below. The same reference numerals as in the arrangement of the first embodiment denote the same parts. As in the first embodiment, this liquid chemical supply apparatus supplies a liquid chemical onto a semiconductor substrate, and includes, midway along the supply path, a mechanism that adds a modifier such as water (e.g., pure water) to the liquid chemical. The third embodiment discloses an example in which an SOG liquid chemical is used as an interlayer dielectric film (e.g., a low-k film).

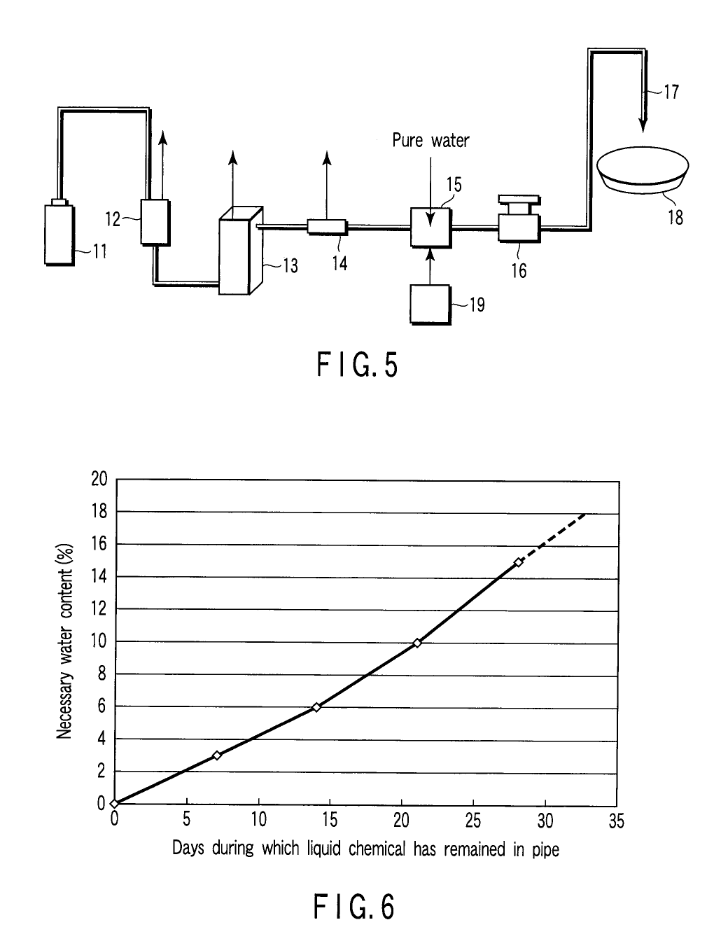

FIG. 5 is a view showing the arrangement of the liquid chemical supply apparatus of the third embodiment. As shown in FIG. 5, this liquid chemical supply apparatus includes a bottle 11, tank unit 12, pump unit 13, filter unit 14, addition adjusting unit (e.g., buffer tank) 15, valve 16, nozzle 17, and addition amount controller 19.

The bottle 11 is loaded in the liquid chemical supply apparatus, and contains the SOG liquid chemical. The SOG liquid chemical in the bottle 11 is supplied to a delivery pipe, and temporarily stored in the tank unit 12 through the delivery pipe. Subsequently, as in the first embodiment, the SOG liquid chemical is supplied to the addition adjusting unit 15. The addition amount controller 19 controls the amount of modifier, e.g., the amount of water to be added to the SOG liquid chemical, in accordance with the time having elapsed since the bottle 11 containing the SOG liquid chemical is loaded in the apparatus. Under the control of the addition amount controller 19, the addition adjusting unit 15 adds, to the SOG liquid chemical, the modifier, e.g., water in the amount set in accordance with the time having elapsed since the bottle 11 containing the SOG liquid chemical is loaded in the apparatus. The SOG liquid chemical to which water is added by the addition adjusting unit 15 is discharged onto a semiconductor substrate 18 from the nozzle 17.

The operation of supplying the SOG liquid chemical onto the semiconductor substrate by using the liquid chemical supply apparatus having the above arrangement will be explained in detail below.

First, it is necessary to obtain an appropriate water addition amount corresponding to the degree of deterioration (or degree of modification) of the SOG liquid chemical. When the SOG liquid chemical deteriorates, its molecular weight rises, and an interlayer dielectric film formed by this SOG liquid chemical becomes porous and lowers its dielectric constant. On the other hand, when the water content in the SOG liquid chemical increases, the interlayer dielectric film becomes dense and raises its dielectric constant. In this embodiment, therefore, the water content by which the dielectric constant of the interlayer insulating film was constant was obtained.

FIG. 6 shows the relationship between the degree of deterioration of the SOG liquid chemical and the water content in the SOG liquid chemical necessary to make the dielectric constant of the interlayer dielectric film constant. The abscissa indicates days having elapsed since the bottle 11 containing the SOG liquid chemical is loaded in the liquid chemical supply apparatus, thereby representing the degree of deterioration of the SOG liquid chemical. The ordinate indicates the water content in the SOG liquid chemical required for the dielectric constant of the interlayer dielectric film formed by the SOG liquid chemical to become constant.

The relationship shown in FIG. 6 reveals that it is necessary to increase the water content in the SOG liquid chemical as the number of days having elapsed since the SOG liquid chemical bottle is loaded increases. More specifically, the following processing was performed. For example, seven days had elapsed at a certain time since the bottle 11 containing the SOG liquid chemical was loaded in the apparatus, i.e., the SOG liquid chemical was injected into the apparatus. Therefore, the addition amount controller 19 injected water into the addition adjusting unit 15 as a buffer tank to set the water content in the SOG liquid chemical at 3%. Also, 14 days had elapsed at another time since the bottle 11 containing the SOG liquid chemical was loaded in the apparatus. Hence, water was injected into the addition adjusting unit 15 to set the water content in the SOG liquid chemical at 6%. Furthermore, 28 days had elapsed at still another time since the bottle 11 containing the SOG liquid chemical was loaded in the apparatus. Accordingly, water was injected into the addition adjusting unit 15 to set the water content in the SOG liquid chemical at 15%.

The dielectric constants of interlayer dielectric films (SOG films) formed by the SOG liquid chemicals given the predetermined water contents described above were measured when the respective corresponding numbers of days had elapsed. Consequently, almost equal dielectric constants were obtained as it was planned.

On the other hand, it is known that when more than 28 days have elapsed since the bottle 11 containing the SOG liquid chemical is loaded in the apparatus, the coating properties become abnormal, the dielectric constant is no longer adjustable, and the thickness of a film to be formed falls outside the range of specifications even if water is added. Therefore, the bottle 11 containing the SOG liquid chemical and loaded in the apparatus was discarded, and the SOG liquid chemical injected into the apparatus was purged.

Note that when the conventional technique that did not add any water to the SOG liquid chemical was used, if more than 14 days had elapsed since the bottle 11 containing the SOG liquid chemical was loaded in the apparatus, an interlayer dielectric film formed by this SOG liquid chemical became porous and decreased its dielectric constant. Accordingly, it was necessary to discard the SOG liquid chemical when more than 14 days had elapsed since the SOG liquid chemical bottle was loaded in the apparatus, so the SOG liquid chemical was wasted. Also, even when 14 days had not elapsed yet since the SOG liquid chemical bottle was loaded in the apparatus, the dielectric constant slightly changed and the electrical characteristics of the device fluctuated due to the time that had elapsed since the SOG liquid chemical bottle was loaded.

By contrast, the third embodiment makes it possible to form an interlayer dielectric film having a predetermined dielectric constant regardless of the time having elapsed since the bottle 11 containing the SOG liquid chemical is loaded in the apparatus. That is, the use period of even a liquid chemical whose performance readily deteriorates can be prolonged while a predetermined performance is maintained.

The degree of deterioration of the liquid chemical may also be determined on the basis of at least one of the time having elapsed since the liquid chemical is supplied to the storage unit, the molecular weight of the liquid chemical, and the film thickness or dielectric constant of a film formed by the liquid chemical. The time having elapsed since a liquid chemical is supplied to the storage unit is the time having elapsed since the bottle containing the SOG liquid chemical is loaded in the liquid chemical supply apparatus, or the time having elapsed since the liquid chemical is externally supplied to the apparatus. Assume that, in this case, the liquid chemical does not deteriorate outside the apparatus and starts deteriorating when supplied to the apparatus.

Note that the third embodiment can form a low-k film as an interlayer dielectric film by using the SOG liquid chemical. Note also that water is used as the modifier of the SOG liquid chemical in the third embodiment, but an alcohol-based material may also be used. The rest of the arrangement and effects are the same as in the first embodiment described earlier.

Each embodiment of the present invention can provide a liquid chemical supply apparatus capable of largely extending the life of a liquid chemical, and a semiconductor device fabrication method using the liquid chemical supply apparatus.

The embodiments described above can be practiced alone, and can also be practiced as they are appropriately combined. In addition, the above-mentioned embodiments each include inventions in various stages. Therefore, it is possible to extract inventions in various stages by appropriately combining the constituent elements disclosed in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A liquid chemical supply apparatus comprising:
a storage unit which stores a liquid chemical;
an addition unit which adds, to the liquid chemical supplied from the storage unit, a modifier in an amount corresponding to a degree of deterioration of the liquid chemical; and
a nozzle unit which supplies, onto a substrate, the liquid chemical to which the modifier is added.

2. The apparatus according to claim 1, wherein the degree of deterioration of the liquid chemical is determined on the basis of a time having elapsed since the storage unit starts storing the liquid chemical.

3. The apparatus according to claim 1, wherein the degree of deterioration of the liquid chemical is determined by at least one of a molecular weight of the liquid chemical and a film thickness of a film formed by the liquid chemical.

4. The apparatus according to claim 1, wherein the modifier comprises one of water and an alcohol-based material.

5. The apparatus according to claim 2, wherein the modifier comprises one of water and an alcohol-based material.

6. The apparatus according to claim 3, wherein the modifier comprises one of water and an alcohol-based material.

7. The apparatus according to claim 1, wherein the storage unit comprises a bottle which is externally loaded in the storage unit and contains the liquid chemical, and a tank unit which stores the liquid chemical supplied from the bottle.

8. The apparatus according to claim 1, wherein the addition unit comprises an addition adjusting unit and an addition amount controller, the addition adjusting unit adjusts the amount of modifier to be added to the liquid chemical under the control of the addition amount controller, and the addition amount controller controls the amount of modifier to be added to the liquid chemical from the addition adjusting unit in accordance with the degree of deterioration of the liquid chemical.

9. A liquid chemical supply apparatus comprising:
a storage unit which stores a liquid chemical, and in which the liquid chemical does not deteriorate regardless of a time having elapsed since the storage of the liquid chemical is started;
an addition unit which receives the liquid chemical supplied from the storage unit, and in which the liquid chemical deteriorates with a time having elapsed since the liquid chemical is supplied from the storage unit, the addition unit adding, to the liquid chemical, a modifier in an amount corresponding to a degree of deterioration of the liquid chemical; and
a nozzle unit which supplies, onto a substrate, the liquid chemical to which the modifier is added.

10. The apparatus according to claim 9, wherein the degree of deterioration of the liquid chemical is determined on the basis of the time having elapsed since the liquid chemical is supplied from the storage unit.

11. The apparatus according to claim 9, wherein the degree of deterioration of the liquid chemical is determined by at least one of a molecular weight of the liquid chemical and a film thickness of a film formed by the liquid chemical.

12. The apparatus according to claim 9, wherein the modifier comprises one of water and an alcohol-based material.

13. The apparatus according to claim 10, wherein the modifier comprises one of water and an alcohol-based material.

14. The apparatus according to claim 11, wherein the modifier comprises one of water and an alcohol-based material.

15. The apparatus according to claim 9, wherein the storage unit comprises a bottle which is externally loaded in the storage unit and contains the liquid chemical, and a tank unit which stores the liquid chemical supplied from the bottle.

16. The apparatus according to claim 9, wherein the addition unit comprises an addition adjusting unit and an addition amount controller, the addition adjusting unit adjusts the amount of modifier to be added to the liquid chemical under the control of the addition amount controller, and the addition amount controller controls the amount of modifier to be added to the liquid chemical from the addition adjusting unit in accordance with the degree of deterioration of the liquid chemical.

17. A semiconductor device fabrication method comprising:
adding, to a liquid chemical supplied from a storage unit storing the liquid chemical, a modifier in an amount corresponding to a degree of deterioration of the liquid chemical;
supplying, onto a substrate, the liquid chemical to which the modifier is added; and
forming a film by using the liquid chemical supplied onto the substrate.

18. The method according to claim 17, wherein the degree of deterioration of the liquid chemical is determined on the basis of a time having elapsed since the storage unit starts storing the liquid chemical.

19. The method according to claim 17, wherein the degree of deterioration of the liquid chemical is determined by at least one of a molecular weight of the liquid chemical and a film thickness of the film formed by the liquid chemical.

20. The method according to claim 17, wherein the liquid chemical comprises a low-k film.
